(19) United States
(12) Patent Application Publication
(10) Pub. No.: US 2026/0105223 A1
(43) Pub. Date: Apr. 16, 2026

(54) METHOD FOR CONSTRUCTING TRANSIENT ELECTROMAGNETIC INVERSION MODEL DRIVEN BY TARGET DATASET FOR EXPLORATION OF METALLIC MINERAL DEPOSITS AND GEOTHERMAL RESOURCES

(71) Applicant: Institute of Geology and Geophysics, Chinese Academy of Sciences, Beijing (CN)

(72) Inventors: Hai LI, Beijing (CN); Ziteng LI, Beijing (CN); Keying LI, Beijing (CN)

(73) Assignee: Institute of Geology and Geophysics, Chinese Academy of Sciences, Beijing (CN)

(21) Appl. No.: 19/421,011

(22) Filed: Dec. 16, 2025

Related U.S. Application Data
(63) Continuation of application No. PCT/CN2025/117142, filed on Aug. 27, 2025.

(30) Foreign Application Priority Data
Aug. 29, 2024 (CN) 202411197283.3

(51) Int. Cl. G06F 30/27; G06N 3/0464

(52) U.S. Cl. CPC G06F 30/27; G06N 3/0464

(57) ABSTRACT

A method for constructing transient electromagnetic inversion model construction method driven by a target dataset is provided, including: constructing an initial training set, and training a first convolutional neural network using the initial training set to obtain an initial transient electromagnetic inversion network model; inputting electromagnetic response data to be measured into the initial transient electromagnetic inversion network model for prediction to obtain resistivity values; performing forward simulation on resistivity values to obtain forward-simulated electromagnetic response data, and constructing prediction data based on forward-simulated electromagnetic response data and resistivity values; extracting similar data to test electromagnetic response data from the initial training set, and constructing a target dataset based on similar data and prediction data; migrating parameters from the initial transient electromagnetic inversion network model to a second convolutional neural network to perform iterative learning on the target dataset, and obtaining a transient electromagnetic inversion model.

### CROSS-REFERENCE TO RELATED APPLICATIONS

This application is a continuation of International Patent Application No. PCT/CN2025/117142, filed on Aug. 27, 2025, and claims priority to Chinese Patent Application No. 202411197283.3, filed on Aug. 29, 2024. The contents of International Patent Application No. PCT/CN2025/117142 and Chinese Patent Application No. 202411197283.3 are hereby incorporated by reference.

### TECHNICAL FIELD

The present disclosure relates to the technical field of transient electromagnetic inversion, and in particular to a method for constructing a transient electromagnetic inversion model driven by a target dataset, which is applicable to exploration of metallic mineral deposits and geothermal resources.

### BACKGROUND

Currently, transient electromagnetic inversion is mainly divided into two types: linear inversion and nonlinear inversion. Linear inversion methods, such as Occam inversion and Marquardt inversion, are highly dependent on the initial model, and the quality of inversion results largely depends on whether a suitable initial model may be found. Nonlinear inversion methods, such as simulated annealing algorithm, particle swarm optimization algorithm, and Bayesian inversion, usually require an enormous computational load due to the complexity of geophysical models. With the improvement of hardware computing capabilities, electromagnetic inversion based on deep learning has become a hot research topic. Vladimir Puzyrev (2019) first explored the potential of deep learning methods in electromagnetic inversion. Subsequently, in recent years, extensive research has been carried out on deep learning-based methods in fields such as controlled source electromagnetic method (CSEM) inversion, magnetotelluric (MT) inversion, and aviation electromagnetic (AEM) inversion.

However, the aforementioned deep learning-based inversion methods are completely data-driven, and their performance largely depends on the richness of the training sample set. When processing data with a distribution different from that of the training sample set, the effect is often unsatisfactory. In response to this, many scholars have made improvements by adding physical constraints to the loss function of the deep learning network to control the training process of the network. For example, Jin et al. (2019) introduced the Jacobian differential operator into the forward model of logging-while-drilling (LWD) electromagnetic responses predicted by a convolutional neural network to construct a composite loss function of the model and data mismatch function. Sun et al. (2020) constructed a forward operator I based on a recurrent neural network (RNN) to simulate wave propagation, realizing unsupervised deep learning seismic inversion, and its training process is equivalent to the optimization of conventional deterministic inversion methods. W. Liu et al. (2022) proposed incorporating the physical laws of magnetotelluric wave propagation into the plain data-driven deep learning method (PlainDNN), adding physics-based mismatched data to the loss function to guide network training, which has been verified in magnetotelluric one-dimensional inversion. In addition, some scholars have combined deep learning with traditional methods to leverage the advantages of both. For example, Asif et al. (2022) predicted the Jacobian matrix in least squares inversion through a neural network, integrated the neural network into traditional least squares inversion, and verified it in transient electromagnetic one-dimensional inversion. On this basis, Asif et al. (2022) obtained the forward operator through neural network training, integrated it into least squares inversion, and finally achieved excellent performance in airborne transient electromagnetic one-dimensional inversion.

Due to the complexity and non-uniqueness of geophysical models, as well as the high requirements for time and computing resources, constructing a large and detailed geophysical dataset for network training is quite challenging. In addition, pure data-driven deep learning methods mainly learn the hidden inversion operator L between input and output within the training set, so when testing data outside the training set, the effect is often unsatisfactory. In other words, data-driven deep learning inversion methods may struggle to handle the fine details between data and models when facing unseen data, unless large-scale training is performed under the condition that the test data has the same statistical distribution. This leads to certain limitations in the practical application of data-driven machine learning methods in geophysical inversion.

Although the improvements of the above two types of methods have reduced the reliance on large-scale data to a certain extent and improved the generalization ability of the network, they have also complicated the network training process to a certain extent and increased the consumption of computing resources during the training phase.

### SUMMARY

An objective of the present disclosure is to provide a method for constructing a transient electromagnetic inversion model driven by a target dataset, which gradually approaches the true inversion result by repeatedly updating the model and adjusting parameters, thereby overcoming the limitations of traditional data-driven methods and improving inversion accuracy and reliability.

To achieve the above objective, the present disclosure provides the following schemes.

A method for constructing a transient electromagnetic inversion model driven by a target dataset, including:
constructing an initial training set, and training a first convolutional neural network using the initial training set to obtain an initial transient electromagnetic inversion network model;
inputting electromagnetic response data to be measured into the initial transient electromagnetic inversion network model for prediction to obtain the resistivity values;
performing forward simulation on the resistivity values to obtain forward-simulated electromagnetic response data, and constructing prediction data based on the forward-simulated electromagnetic response data and the resistivity values;
extracting similar data to the test electromagnetic response data from the initial training set, and constructing a target dataset based on the similar data and the prediction data;
migrating parameters from the initial transient electromagnetic inversion network model to a second convolutional neural network to perform iterative learning on the target dataset, and obtaining a transient electromagnetic inversion model, and using the transient electromagnetic inversion model to convert the electromagnetic response data to be measured into resistivity values for a plurality of underground layers of the underground geological structure, and applying the resistivity values in exploration of metal mineral deposits and geothermal resources.

Optionally, obtaining the initial training set includes:
presetting thicknesses of a top layer and boundary depths of a bottom of an underground geological structure, and dividing the underground geological structure into multiple layers according to a method of cumulative increment of thickness of each layer;
determining multiple control points between the top layer and the bottom layer, interpolating the control points to obtain resistivity-thickness sample data between the top layer and the bottom layer;
performing transient electromagnetic one-dimensional numerical simulation according to the resistivity-thickness sample data to obtain corresponding electromagnetic responses; and
obtaining a sample dataset based on resistivity values and the corresponding electromagnetic responses, and dividing the initial training set from the sample dataset.

Optionally, interpolating the control points includes: performing interpolation using a B-spline interpolation method.

Optionally, a convolutional neural network includes an input layer, an output layer, convolutional layers, and fully connected layers, where the input layer is configured for inputting the electromagnetic responses, the output layer is configured for outputting the resistivity values, and data features extracted by the convolutional layers are input to the fully connected layers.

Optionally, extracting the similar data to the test electromagnetic response data from the initial training set includes:
obtaining a relative average response error between electromagnetic response data and the electromagnetic response data to be measured in the initial training set; obtaining electromagnetic response data in the initial training set corresponding to a relative average response error within a preset range as similar electromagnetic response data, and extracting resistivity values corresponding to the similar electromagnetic response data in the initial training set to obtain the similar data.

The disclosure also provides a target dataset-driven transient electromagnetic inversion method for constructing a transient electromagnetic inversion model driven by a target dataset for constructing the transient electromagnetic inversion model, and then inputting electromagnetic response data to be predicted into the transient electromagnetic inversion model to obtain predicted resistivity values.

The beneficial effects of the present disclosure are: the present disclosure aims to improve the accuracy of the network in inverting test data when performing deep learning inversion on the test data through an iterative training strategy. In this method, the true inversion result is gradually approached by repeatedly updating the model and adjusting parameters, thereby overcoming the limitations of traditional data-driven methods and improving inversion accuracy and reliability. In particular, the method is helpful in exploration of metal mineral deposits and geothermal resources so that the improved inversion accuracy improves the reliability of geophysical exploration and resource evaluation.

### BRIEF DESCRIPTION OF THE DRAWINGS

In order to explain the technical schemes in the embodiments of the present disclosure or the prior art more clearly, the following briefly introduces the drawings required for the embodiments. Obviously, the drawings in the following description are only some embodiments of the present disclosure, and those skilled in the art may obtain other drawings according to these drawings without creative labor.

FIG. 1 is a framework diagram of the target dataset-driven transient electromagnetic inversion model construction method according to an embodiment of the present disclosure.

FIG. 2 is a schematic diagram of sample set data generation according to an embodiment of the present disclosure.

FIG. 3 is a framework diagram of the iterative inversion network driven by the target dataset according to an embodiment of the present disclosure.

FIG. 4 is a loss graph of network model training according to an embodiment of the present disclosure.

FIG. 5A, FIG. 5B, FIG. 5C, FIG. 5D, FIG. 5E and FIG. 5F are performance evaluation graphs of the initial network model according to an embodiment of the present disclosure.

FIG. 6 is a comparison graph of response errors of the iterative inversion network driven by the target dataset according to an embodiment of the present disclosure.

FIG. 7A and FIG. 7B are comparison graphs of a certain test sample point using different methods according to an embodiment of the present disclosure, where FIG. 7A is a response data fitting graph, and FIG. 7B is a resistivity value fitting graph.

### DETAILED DESCRIPTION OF THE EMBODIMENT

The technical schemes in the embodiment of the present disclosure will be clearly and completely described below with reference to the drawings in the embodiment of the present disclosure. Obviously, the described embodiment is only a part of the embodiments of the present disclosure, not all of them. Based on the embodiment of the present disclosure, all other embodiments obtained by those skilled in the art without creative labor shall fall within the protection scope of the present disclosure.

To make the above objectives, features, and advantages of the present disclosure more obvious and understandable, the present disclosure is further described in detail below with reference to the drawings and specific embodiment.

The embodiment provides a method for constructing transient electromagnetic inversion model driven by a target dataset, including:
constructing an initial training set, and training a first convolutional neural network using the initial training set to obtain an initial transient electromagnetic inversion network model;
inputting electromagnetic response data to be measured into the initial transient electromagnetic inversion network model for prediction to obtain the resistivity values;
performing forward simulation on the resistivity values to obtain forward-simulated electromagnetic response data, and constructing prediction data based on the forward-simulated electromagnetic response data and the resistivity values; and
extracting similar data to the test electromagnetic response data from the initial training set, and constructing a target dataset based on the similar data and the prediction data;
in an embodiment, extracting the similar data to the test electromagnetic response data from the initial training set includes:
obtaining a relative average response error between electromagnetic response data and the electromagnetic response data to be measured in the initial training set; obtaining electromagnetic response data in the initial training set corresponding to a relative average response error within a preset range as similar electromagnetic response data, and extracting resistivity values corresponding to the similar electromagnetic response data in the initial training set to obtain the similar data.

Parameters from the initial transient electromagnetic inversion network model are migrated to a second convolutional neural network to perform iterative learning on the target dataset, and a transient electromagnetic inversion model is obtained.

In an embodiment, obtaining the initial training set includes: presetting thicknesses of a top layer and boundary depths of a bottom of an underground geological structure, and dividing the underground geological structure into multiple layers according to a method of cumulative increment of thickness of each layer; determining multiple control points between the top layer and the bottom layer, interpolating the control points to obtain resistivity-thickness sample data between the top layer and the bottom layer; performing transient electromagnetic one-dimensional numerical simulation according to the resistivity-thickness sample data to obtain corresponding electromagnetic responses; and obtaining a sample dataset based on resistivity values and the corresponding electromagnetic responses, and dividing the initial training set from the sample dataset.

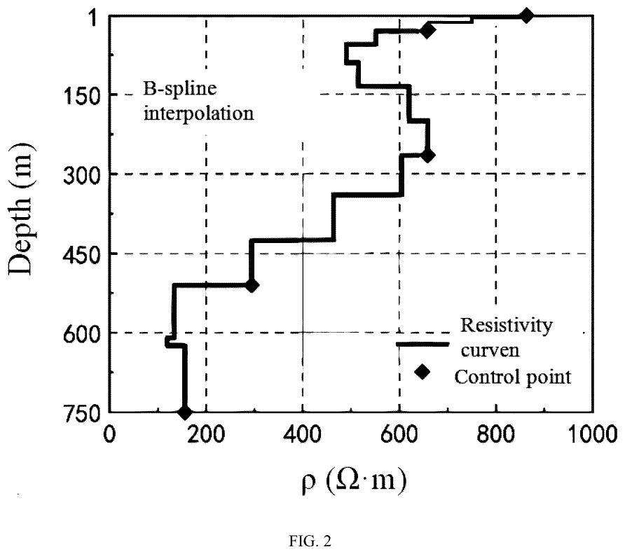

Specifically, it is considered that the resistivity values of actual underground strata are usually continuously distributed rather than segmented, and the continuous distribution characteristic may better reflect the complexity of the underground geological structure. Therefore, in order to generate relatively smooth and vertically continuous underground resistivity values, this embodiment adopts the following method for sample set data generation: first, the top layer thickness is set to 1 meter (m) and the bottom boundary depth of the last layer is set to 750 m, and it is divided into 15 layers according to the method of cumulative increment of thickness of each layer to ensure that the random characteristics of the underground resistivity distribution are fully reflected; 5 control points are determined between 1 m and 750 m, as shown by the dark points in FIG. 2, where the depths of 2 control points are fixed at 1 m and 750 m, and the remaining 3 control points are randomly determined, but the depth between control points is required to be within 50 m to 200 m. The resistivity of the control points is randomly generated within 10 ohm meters (Ω·m) to 1000 Ω·m, and interpolation is performed using the B-spline interpolation method based on the 5 control points to make the resistivity curve smoother, and finally, continuously distributed resistivity values from 1 m to 750 m are obtained, as shown in FIG. 2. A rectangular loop source device is adopted, and the generated resistivity-thickness sample data is substituted into the transient electromagnetic one-dimensional numerical simulation method to calculate the corresponding electromagnetic responses. The length and width of the coil are 500 m, the number of receiving time channels is 61, the sampling time is 1×10⁻⁴ to 1×10⁻¹ seconds, and the transmitting current is 10 amperes (A).

In an embodiment, a convolutional neural network includes an input layer, an output layer, convolutional layers, and fully connected layers, where the input layer is configured for inputting the electromagnetic responses, the output layer is configured for outputting the resistivity values, and data features extracted by the convolutional layers are input to the fully connected layers.

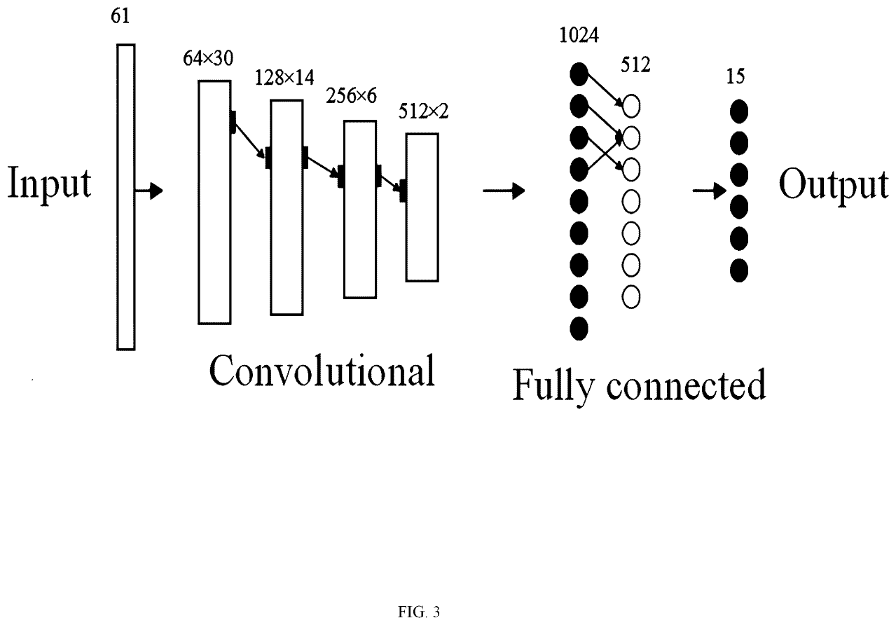

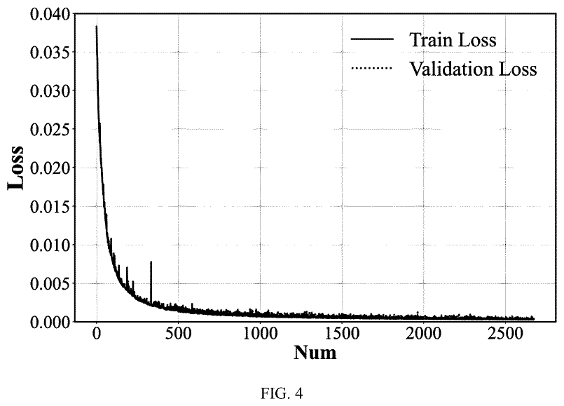

Specifically, the framework of the convolutional neural network model adopted is shown in FIG. 3. The input of the network is electromagnetic response data, and the output is resistivity values. The network structure mainly includes an input layer, an output layer, 4 convolutional layers, and 2 fully connected layers. The input layer has 61 neurons, representing 61 electromagnetic response values; the output layer has 15 neurons, corresponding to 15 layers of resistivity values. The convolution kernel sizes of the 4 convolutional layers are 2×1, 3×1, 3×1, and 3×1 in sequence, the number of convolution kernels is 64, 128, 256, and 512 in sequence, and the stride is 1 for all; where the pooling layer adopts Max-pooling with a size of 2×1 and a stride of 2. The data features extracted by the convolutional layers are input to the fully connected layers through a flattening layer, and the number of neurons in the 2 fully connected layers is 1024 and 512 in sequence. The activation function adopts the hyperbolic tangent function (tanh) for all. To quantitatively evaluate the convergence of the network training process, the following loss function is defined:

$$ℓ = \frac{1}{N} {\sum }_{j = 1}^{N} \frac{\vert {y}_{j} - {\hat{y}}_{j} \vert}{{y}_{j}} \qquad ( 1 )$$

where N represents the number of layers of resistivity values, ŷⱼ represents the j-th layer resistivity value predicted by the network prediction model, and yⱼ represents the resistivity value corresponding to the true geoelectric model.

The network training adopts the Adam optimizer, and the hyperparameters in the network are set as follows: learning rate (lr)=0.0001, data batch size=1024, number of training epochs=5000, and the training strategy adopts an early stopping mechanism. A total of 40,000 sample datasets are generated, and the dataset is divided according to the ratio of training set:validation set:test set=6.3:2.7:1.0.

FIG. 4 is a graph of the loss function of the model network training, where the dashed line is the validation set error and the solid line is the training set error; the early stopping mechanism is adopted, and it is able to be seen that there is no overfitting during the model training process. It is able to be seen that the loss value on the training set (Train loss) and the loss value on the validation set (Validation loss) continue to decrease during the training process and finally converge. The decrease in the loss value on the training set indicates that the model may gradually learn the patterns and laws in the training data and continuously optimize the model parameters. This indicates that the model does not have obvious overfitting during the training process and has strong fitting ability.

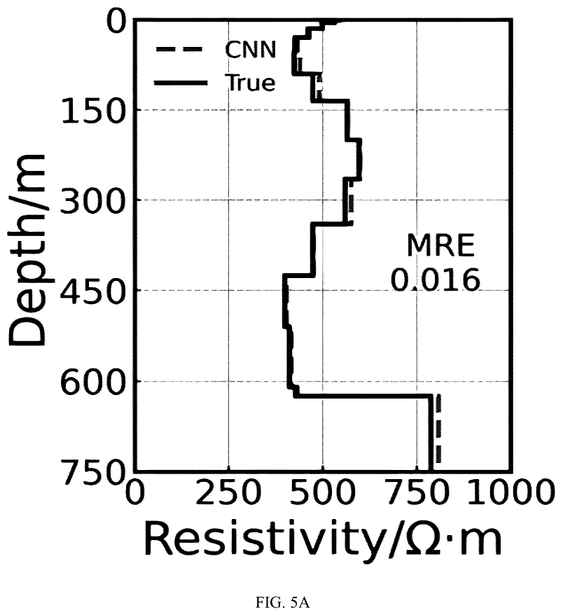

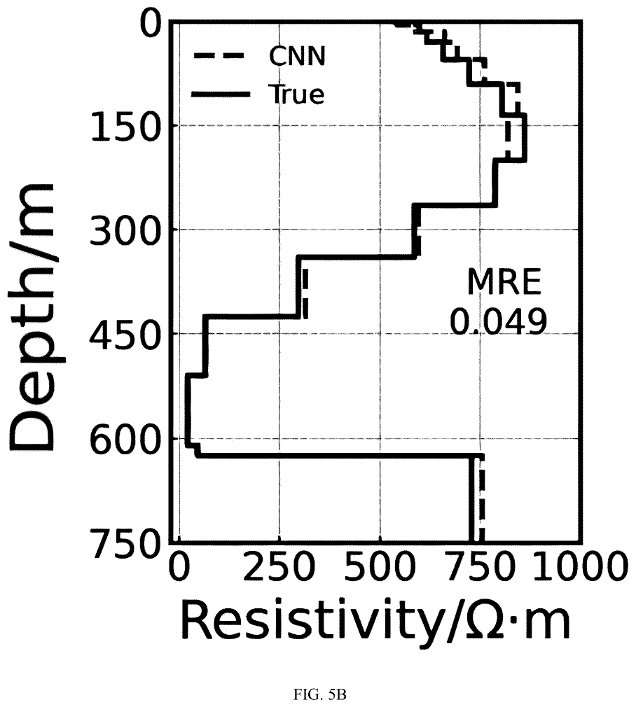

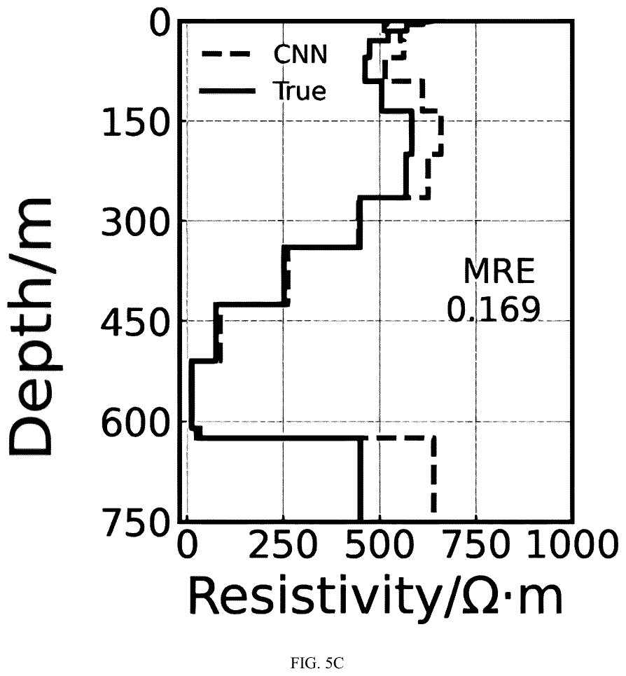

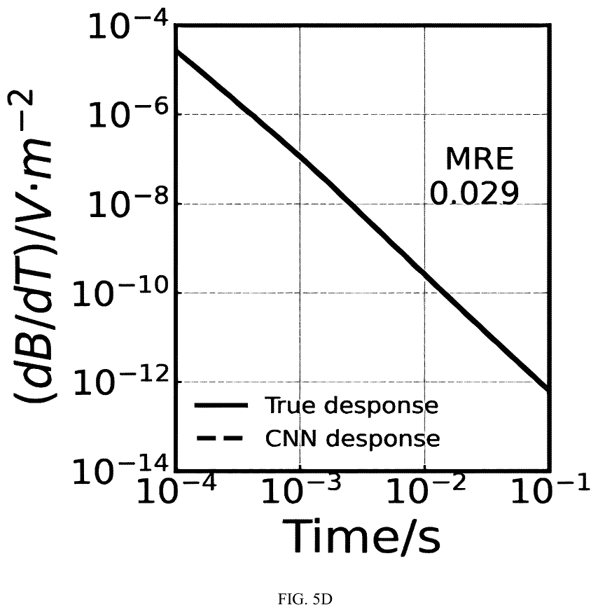

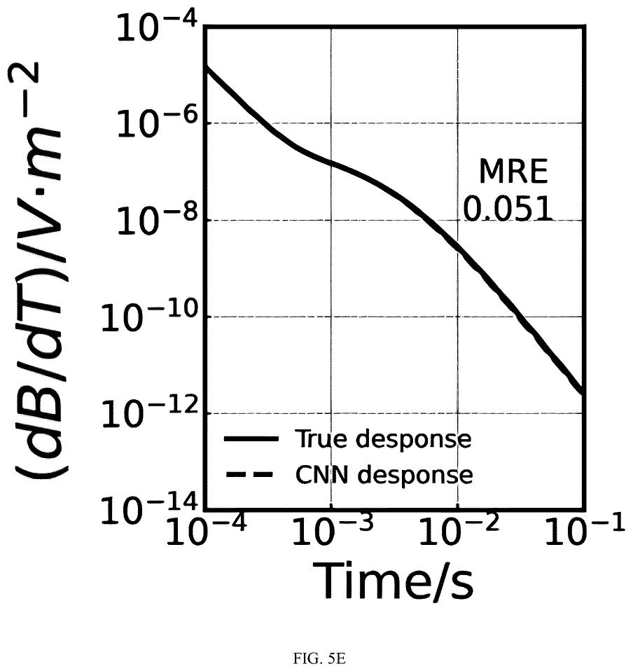

In this embodiment, three geoelectric model data corresponding to the minimum, average, and maximum of relative average errors are selected from the test set. FIG. 5A, FIG. 5B, FIG. 5C, FIG. 5D, FIG. 5E and FIG. 5F show the comparison graphs of the resistivity-depth curves between the original models and the inverted models of these three models, as well as the comparison graphs of the electromagnetic responses between the original models and the inverted models. FIG. 5A, FIG. 5B, FIG. 5C, FIG. 5D, FIG. 5E and FIG. 5F select three data with relative average errors of minimum, average, and maximum, and draw the resistivity-depth graphs (FIG. 5A, FIG. 5B and FIG. 5C) of the original geoelectric models and the inverted geoelectric models and the electromagnetic response signal graphs (FIG. 5D, FIG. 5E and FIG. 5F) of the original geoelectric models and the inverted geoelectric models. It is able to be observed from the figure that the fitting between the inverted models and the original models is good. Although there are certain gaps in some layers, the overall is still within an acceptable range. Especially for the model with the maximum relative average error, although there are large errors in the resistivity prediction of some layers, the overall trend of resistivity with depth is consistent with the original model, and the corresponding electromagnetic response error is only 9.4 percent (%). This further indicates that the inversion result has high accuracy, which satisfies the assumption that the deep learning inversion method has high efficiency and certain guaranteed accuracy.

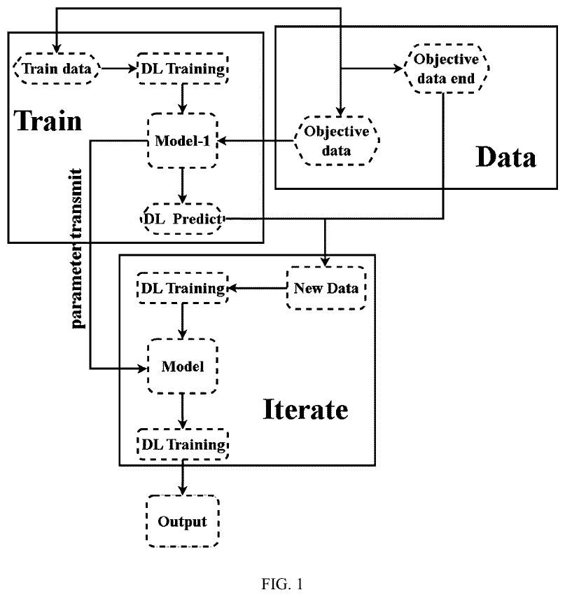

Specifically, as shown in FIG. 1, the upper right part is the dataset required for iterative inversion, and the lower part is the iterative training part. First, an initial training set is generated through numerical simulation, that is, the Train data in the upper left module, then training is performed through the convolutional neural network model to obtain the initial transient electromagnetic inversion network model, and finally the first prediction is performed on the electromagnetic response data to be measured, that is, the objective data in the upper right module, to obtain the corresponding resistivity value DL Predict. Then the data in the Train data whose relative average response error (as shown in Formula 2) with the test electromagnetic response data (objective data) is within 5% is extracted, that is, objective data end, including the corresponding resistivity values. Then, merge objective data end with DL Predict (resistivity values) and the electromagnetic responses obtained by forward simulation of DL Predict to form the dataset New Data required for iterative inversion (in the lower module). Finally, a transfer learning strategy is adopted for the initial network Model-1, that is, the network framework keeps unchanged, the model parameters are migrated in Model-1 to Model (second convolutional neural network) to initialize the model parameters, then learn about New Data, and this process is iterated multiple times to realize iterative inversion driven by the target dataset.

$$error = \frac{1}{M} {\sum }_{j = 1}^{M} \frac{\vert {d}_{j} - {\hat{d}}_{j} \vert}{{d}_{j}} \qquad ( 2 )$$

where M is a number of time channels, dj is a true electromagnetic response of a j-th time channel, and \hat{d}j is a network-predicted electromagnetic response of the j-th time channel; and

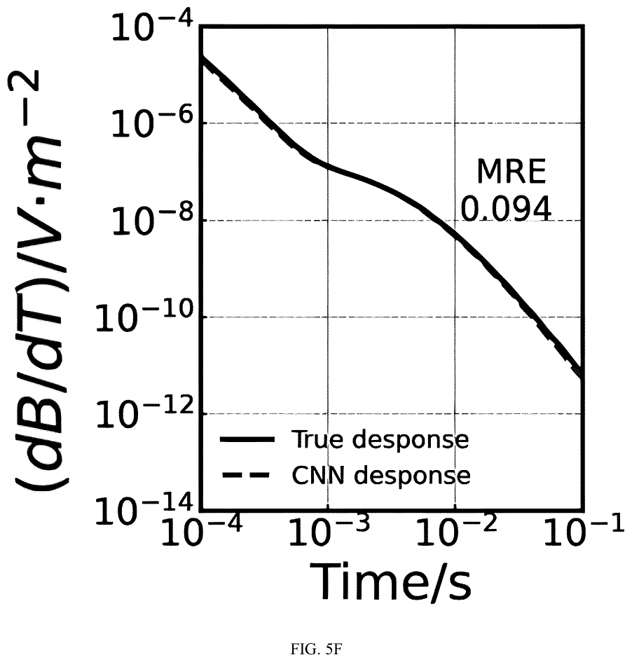

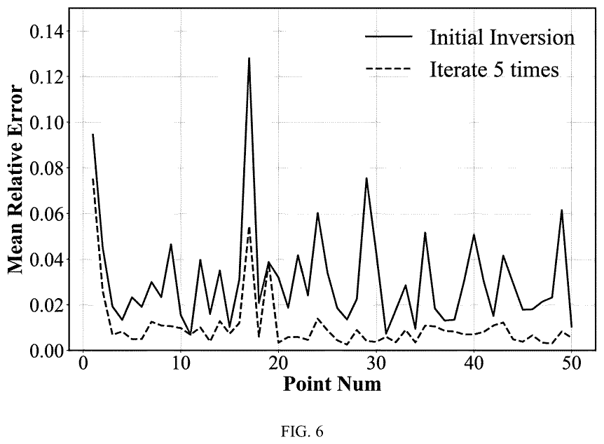

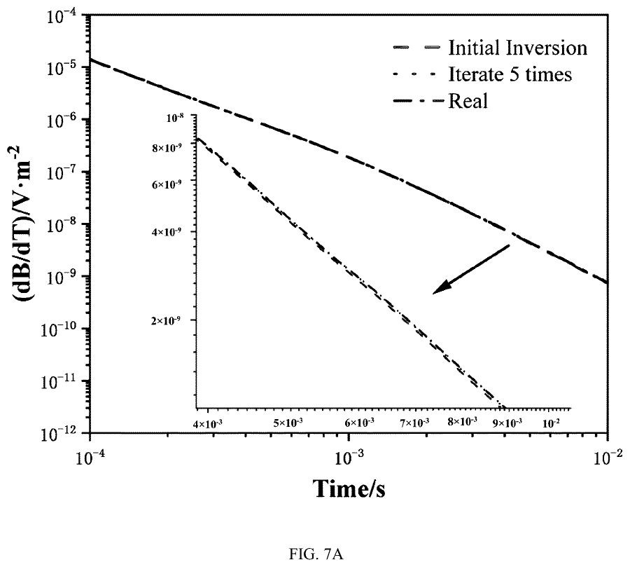

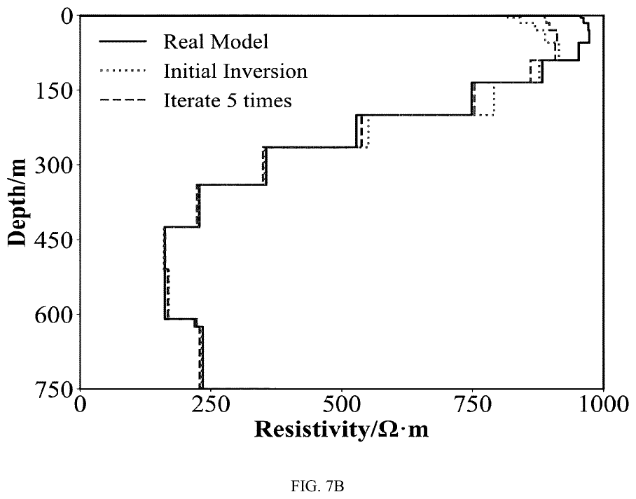

The solid line in FIG. 6 is the model response error of the initial network model for predicting 50 data to be measured, and the dashed line is the model response error predicted by the target dataset-driven iterative inversion network. It is able to be clearly observed from FIG. 6 that after the target dataset-driven iterative inversion, except for individual data, the response error of the test data is generally reduced to a low level, indicating that the target dataset-driven iterative inversion strategy has a certain effect. In addition, by comparing the results of a certain test sample point using different methods as shown in FIG. 7A and FIG. 7B, where the dash-dot line is the true value, the dashed line is the result obtained by the initial network inversion, and the dotted line is the result after 5 iterations of the target dataset-driven iterative inversion network. It is able to be observed from the subgraph in FIG. 7A that after 5 iterations, the response error of the data approaches the true response value, and the response accuracy is improved to a certain extent; in addition, it is able to be clearly observed from FIG. 7B that the result after 5 iterations (dashed line) is closer to the true resistivity value, which is more obvious in the shallow part with a depth of 100 m to 200 m. In summary, this embodiment realizes the improvement of the network's inversion accuracy of the network for the data to be measured through simple iterative inversion.

The transient electromagnetic inversion network based on deep learning, without any measures, the relative average model error and relative average response error for 50 samples different from the training set (the number of measured data samples of a single survey line is relatively close) are 0.0504 and 0.0310, respectively. The accuracy is high, which satisfies the assumption that the deep learning inversion method has high efficiency and certain guaranteed accuracy.

The target dataset proposed in this embodiment includes two parts.
(1) Similar data similar to the data to be measured in the training set, that is, the dataset with a response error less than a specified threshold (default 5%). (2) A dataset includes the resistivity values predicted by the network and corresponding responses, and a transfer learning strategy is adopted for the initial training model to learn the target dataset. After 5 iterations of inversion, the relative average model error and relative average response error of the proposed method are 0.0379 and 0.0105, respectively. Compared with the initial prediction, both the model error and the response error are reduced by 3 to 5 times.

In summary, this embodiment realizes the improvement of the inversion accuracy of the network for test data through simple iterative inversion.

This embodiment also provides a target dataset-driven transient electromagnetic inversion method, which uses the method for constructing transient electromagnetic inversion model driven by target dataset for constructing a transient electromagnetic inversion model, and inputting the electromagnetic response data to be predicted into the transient electromagnetic inversion model to obtain predicted resistivity values.

The above-described embodiment is only descriptions of the preferred modes of the present disclosure, and is not intended to limit the scope of the present disclosure. Without departing from the design spirit of the present disclosure, various modifications and improvements made by those skilled in the art to the technical solutions of the present disclosure shall fall within the protection scope defined by the claims of the present disclosure.

What is claimed is:

1. A method for constructing transient electromagnetic inversion model driven by a target dataset, comprising:
constructing an initial training set, and training a first convolutional neural network using the initial training set to obtain an initial transient electromagnetic inversion network model;
wherein obtaining the initial training set comprises:
presetting thicknesses of a top layer and boundary depths of a bottom of an underground geological structure, and dividing into a plurality of layers according to a method of cumulative increment of thickness of each layer;
determining a plurality of control points between the top layer and the bottom layer, interpolating the control points to obtain resistivity-thickness sample data between the top layer and the bottom layer;
performing transient electromagnetic one-dimensional numerical simulation according to the resistivity-thickness sample data to obtain corresponding electromagnetic responses;
obtaining a sample dataset based on resistivity values and the corresponding electromagnetic responses, and dividing the initial training set from the sample dataset;
a convolutional neural network comprises an input layer, an output layer, convolutional layers, and fully connected layers, wherein the input layer is configured for inputting the electromagnetic responses, the output layer is configured for outputting the resistivity values, and data features extracted by the convolutional layers are input to the fully connected layers;
inputting electromagnetic response data to be measured into the initial transient electromagnetic inversion network model for prediction to obtain the resistivity values;
performing forward simulation on the resistivity values to obtain forward-simulated electromagnetic response data, and constructing prediction data based on the forward-simulated electromagnetic response data and the resistivity values;
extracting similar data to the test electromagnetic response data from the initial training set, and constructing a target dataset based on the similar data and the prediction data;
wherein extracting the similar data to the test electromagnetic response data from the initial training set comprises:
obtaining a relative average response error between electromagnetic response data and the electromagnetic response data to be measured in the initial training set; obtaining electromagnetic response data in the initial training set corresponding to a relative average response error within a preset range as similar electromagnetic response data, and extracting resistivity values corresponding to the similar electromagnetic response data in the initial training set to obtain the similar data;
calculating the relative average response error comprises:
$$error = \frac{1}{M} {\sum }_{j = 1}^{M} \frac{\vert {d}_{j} - {\hat{d}}_{j} \vert}{{d}_{j}} ;$$
wherein M is a number of time channels, dⱼ is a true electromagnetic response of a j-th time channel, and \hat{d}ⱼ is a network-predicted electromagnetic response of the j-th time channel; and
migrating parameters from the initial transient electromagnetic inversion network model to a second convolutional neural network to perform iterative learning on the target dataset, and obtaining a transient electromagnetic inversion model.

2. The method according to claim 1, wherein interpolating the control points comprises: performing interpolation using a B-spline interpolation method.

3. A target dataset-driven transient electromagnetic inversion method, wherein the method uses the method for constructing transient electromagnetic inversion model according to claim 1 for constructing transient electromagnetic inversion model, and inputting electromagnetic response data to be predicted into the transient electromagnetic inversion model to obtain predicted resistivity values.
